(19) United States
(12) Patent Application Publication
(10) Pub. No.: US 2009/0323753 A1
(43) Pub. Date: Dec. 31, 2009

(54) Apparatus for Inscribing Containers

(75) Inventors: Franz Gmeiner, Sinzing/Eilsbrunn (DE); Heinz Humele, Thalmassing (DE)

Correspondence Address: RISSMAN HENDRICKS & OLIVERIO, LLP, 100 Cambridge Street, Suite 2101, BOSTON, MA, 02114, US

(73) Assignee: KRONES AG, Neutraubling (DE)

(21) Appl. No.: 12/493,133

(22) Filed: Jun. 26, 2009

(30) Foreign Application Priority Data
Jun. 30, 2008 (DE) 10 2008 030 868.4

(51) Int. Cl. H01S 5/40

(52) U.S. Cl. 372/50.122

(57) ABSTRACT

An apparatus for inscribing containers may include an inscription unit. The inscription unit may include a plurality of laser light sources and a plurality of light discharge bodies. The light discharge bodies may be arranged next to one another. The laser light sources may be solid-state lasers. Each light discharge body may be connected to a respective one of the laser light sources. The light discharge bodies may be configured to direct laser light from the laser light sources onto containers to be inscribed.

### CROSS-REFERENCE TO RELATED APPLICATION

This application claims the benefit of priority of German Patent Application No. 10 2008 030 868.4, filed Jun. 30, 2008, pursuant to 35 U.S.C. 119(a)-(d), the disclosure of which is incorporated herein by reference in its entirety as if fully set forth herein.

### TECHNICAL FIELD

The present disclosure relates to an apparatus for inscribing containers.

### BACKGROUND

From the prior art and, particularly, in the beverage-processing industry, it is known to inscribe containers such as, for example, plastic containers. For example, it is possible to provide a beverage-filled container with an imprint which indicates the filling date and optionally a shelf life. For this, various printing methods are known from the prior art.

One conventional printing method consists in using a plurality of CO₂ lasers, i.e. gas lasers, which emit laser light onto the containers to be inscribed and in this way bring about the inscription of the containers. However, such gas laser arrangements are cost-intensive and also take up a lot of space.

It may therefore be desirable to provide an apparatus for inscribing containers which is easier to handle and more cost-efficient. This may be achieved by apparatuses according to the disclosure.

### SUMMARY OF INVENTION

An apparatus according to the disclosure for inscribing containers may comprise an inscription unit, wherein this inscription unit comprises a plurality of laser light sources, which can be controlled independently of one another, and also a plurality of light discharge bodies, which are arranged next to one another and which direct laser light onto the containers to be inscribed. According to the disclosure, the laser light sources may be solid-state lasers. Contrary to the prior art, therefore, it is proposed to use, instead of gas lasers, solid-state lasers, which are less expensive to produce and meanwhile also allow high power levels or power levels which are sufficient for inscribing, for example, plastic containers.

It has surprisingly been found that the emission wavelengths typical of solid-state lasers, which lie in the region of 500 nm-1500 nm and therefore differ considerably from the wavelengths typical of gas lasers, are also suitable for inscribing plastic containers.

In an exemplary embodiment, the laser light sources may be semiconductor lasers and in some exemplary aspects diode lasers. As mentioned above, such diode lasers are inexpensive to produce, which in turn has an effect on the apparatus as a whole. The laser light is directed onto the containers via the light discharge bodies, which may be, for example, the ends of glass fibres.

According to some aspects, the light discharge bodies may be connected to the laser light sources via a plurality of optical fibres. These optical fibres may comprise, for example, glass fibres and the like. In this way, the actual laser light sources can be positioned at a different location than the light discharge bodies, resulting in a greater spatial independence for the apparatus. The cooling of the laser light sources can also be facilitated in this way.

According to various aspects, a so-called direct diode laser may be used as the laser light source. In the prior art, diode lasers are sometimes usually used to pump other laser devices, such as YAG lasers for example. However, the output radiation of the diode lasers described here is not used for pumping, but rather is directed directly onto the containers to be inscribed. One laser light source may therefore be assigned to each light discharge body.

In some aspects, the light discharge bodies may be arranged in a common housing. In this way, it is possible to provide a relatively small housing which comprises a plurality of light discharge bodies for inscribing the containers.

In various aspects, at least two light discharge bodies are offset relative to one another in a transport direction of the containers. It is thus proposed that the containers may be transported individually by means of a transport device, and the light discharge bodies are offset relative to one another in this transport direction. In this way, the individual laser light sources for producing certain imprints do not have to be activated simultaneously, but rather activation can take place in a manner offset over time. In this way, voltage peaks in the power supply to the laser light sources can be avoided.

According to some aspects, the light discharge bodies may be arranged along a diagonal line relative to a longitudinal direction of the containers to be inscribed. This means that all of the light discharge bodies are respectively offset relative to one another, wherein this procedure also means that all of the laser light sources can be activated at different points in time.

According to various aspects, the laser light sources may be light sources that emit pulsed radiation, or so-called quasi-continuous radiation. However, use may also be made of lasers that emit continuous light (so-called CW “continuous wave” lasers).

Use may be made of between five and 30 light discharge bodies, and in some aspects between 10 and 20 light discharge bodies. In this way, a fine resolution of the characters to be printed in each case is possible.

In an exemplary embodiment, the apparatus may comprise a transport device which transports the containers individually.

In an exemplary embodiment, the laser sources may emit radiation in a wavelength range between 700 nm and 1300 nm. Use may be made of radiation in a near-infrared (NIR) spectral range.

In an exemplary embodiment, the optical fibres may run at least partially alongside one another. This means that a bundle of optical fibres coming from the laser sources is guided in the direction of the containers to be inscribed.

In various aspects, at least one refractive element may be arranged between the light discharge bodies and the containers. This may be, for example, lenses and, in some aspects, cylindrical lenses, which focus the radiation coming from the light discharge bodies onto the containers.

According to various aspects, the light discharge bodies can be moved jointly in the transport direction of the containers. By virtue of this mobility, it is possible for example to compensate differences in speed which may occur during transport of the containers. In some aspects, the light discharge bodies are arranged on a carriage. In addition, it would also be possible to move the light discharge bodies in a direction perpendicular to the transport direction and, in some aspects, to a direction running parallel to the longitudinal direction of the containers.

In an exemplary embodiment, the apparatus may comprise a control device which controls a movement of the light discharge bodies in the transport direction of the containers as a function of the transport speed of the containers. If, for example, the operating speed of the transport device has to be reduced, this would mean that the relative speed between the containers and the light discharge bodies is reduced. This would lead to a change in the printed image. In this case, it would be possible to regulate or adapt the relative speed between the light discharge bodies and the containers by moving the light discharge bodies in this case counter to the transport direction of the containers.

In this case, a corresponding container could still in principle be inscribed even in the event of a standstill of a transport device, by moving the light discharge bodies at the normal speed counter to the transport direction of the containers. However, it would also be possible to vary other parameters, such as for example the power of the laser light sources, as a function of the transport speed.

In various aspects, the transport device may comprise rotary devices which rotate the containers about their own axis. In this way, an imprint can be produced in a larger area in the circumferential direction of the containers. It would also be possible to use such a rotary device to vary the relative speed between the outer wall of the respective containers and the inscription unit.

The present disclosure also relates to a method for inscribing containers, wherein the containers are transported individually by a transport device along a predefined path and during this transport are inscribed individually by means of an apparatus for inscribing the containers. The apparatus for inscribing the containers may comprise a plurality of light discharge bodies which are arranged next to one another and which direct laser light onto the containers, wherein the containers move relative to the light discharge bodies during the inscription. According to the disclosure, the light discharge bodies are supplied with laser light by a plurality of laser light sources, wherein the laser light sources are solid-state laser light sources.

As the laser light sources, use may be made of diode lasers including, for example, the abovementioned direct diode lasers.

In some aspects, the laser light sources transmit the laser light to the light discharge bodies by means of a plurality of optical fibres. The light discharge bodies may be separate bodies; however, it would also be possible that the light discharge bodies are the ends of the aforementioned optical fibres.

According to various aspects, the light discharge bodies are moved at least intermittently.

Further advantages and embodiments may emerge from the appended drawings:

### BRIEF DESCRIPTION OF THE DRAWINGS

In the drawings:

FIG. 1 shows a schematic view of an apparatus according to the disclosure for inscribing containers; and

FIG. 2 shows a plan view of an arrangement comprising a plurality of light discharge bodies.

### DETAILED DESCRIPTION

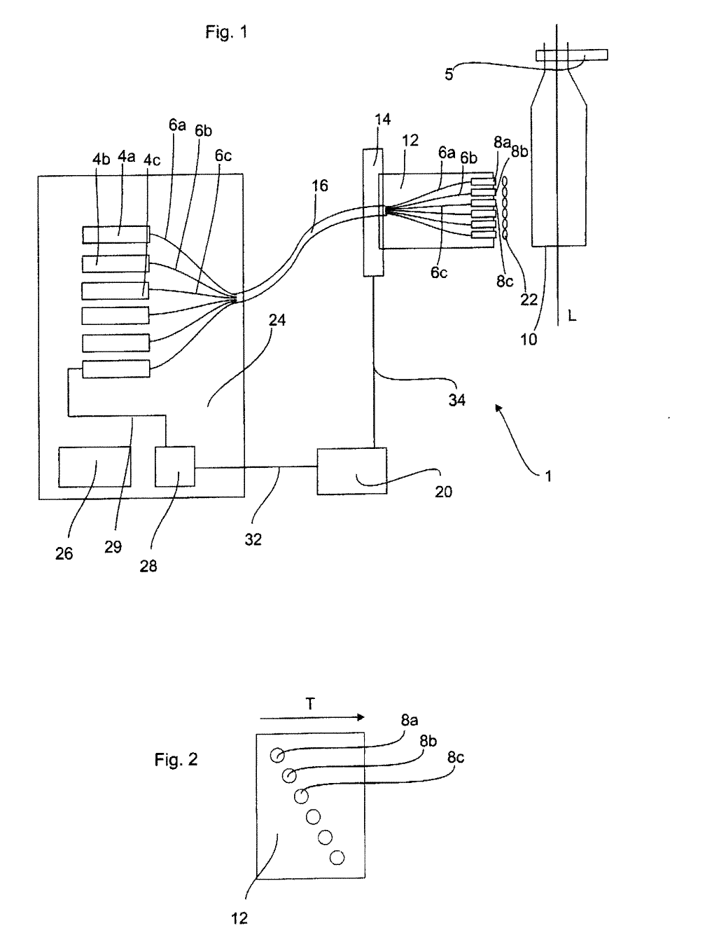

FIG. 1 shows a schematic view of an apparatus 1 according to the disclosure for inscribing containers. A transport device 5 (shown only schematically) may be provided, which conveys the containers 10 perpendicular to the plane of the figure in FIG. 1. The transport device 5 may be for example a transport starwheel or the like, on which there is arranged a plurality of gripping elements which convey the containers 10 for example at their carrying ring. The containers 10 may comprise, for example, plastic containers. However, other transport devices such as air conveyors and the like would in principle also be conceivable.

Reference 12 denotes a housing, in which a plurality of light discharge bodies 8a, 8b, 8c are arranged. Here, the individual light discharge bodies 8a, 8b, 8c are arranged in a row next to one another. These light discharge bodies 8a, 8b, 8c are connected to respective laser light sources 4a, 4b, 4c via optical fibres 6a, 6b, 6c. As mentioned above, it is also conceivable that the light discharge bodies 8a, 8b, 8c are the ends of the individual optical fibres. Reference 14 denotes a holder or a carrier, on which the housing containing the individual light discharge bodies 8a, 8b, 8c is arranged. Here, this housing 12 is, according to some aspects, movable in a direction perpendicular to the plane of the figure. Furthermore, it would also be possible that the housing 12 containing the light discharge bodies 8a, 8b, 8c is displaceable in the longitudinal direction L of the container, in order to apply imprints at different heights of the container.

The laser light sources 4a, 4b, 4c are likewise arranged in a stationary housing 24. These laser sources 4a, 4b, 4c may be spaced apart from one another by a greater distance than the individual light discharge bodies, in order in this way to bring about the temperature equalisation more easily.

Reference 28 denotes a control device which is connected to the individual laser light sources 4a, 4b, 4c via a connection 29. For reasons of simplification, however, just one of these connections 29 is shown here. The individual optical fibres are guided alongside one another in a common cable connection 16.

Reference 26 denotes a power supply or mains connection for supplying power to the individual laser sources 4a, 4b, 4c. The control device 28 means that the individual laser light sources can be controlled independently of one another. In this way, laser light can in each case be conducted via the optical fibres to the light discharge bodies 8a, 8b, 8c and said laser light can in turn be applied via lens elements to the container. In this way, symbols, letters and characters, such as a best-before date for example, can be imprinted on the container in the manner of a matrix print. It should be mentioned that the container 10 is shown on a greatly reduced scale here and in actual fact usually only a small area for example in the region of the bottom of the container is printed.

Reference 20 denotes a central control device which controls, for example, the transport device 5. At the same time, this central control device is connected to the control device 28 via a connection 32. Depending on a transport speed of the containers, it is possible to control for example the power of the individual laser light sources 4a, 4b, 4c. The central control device 20 is also connected to a drive for the housing 12 via a further communication connection 34, so that the movement of the housing 12 containing the light discharge bodies 8a, 8b, 8c can also be controlled as a function of the transport speed of the containers.

Reference 22 denotes refractive elements which are arranged between the light discharge bodies 8a, 8b, 8c and the container. These refractive elements may be for example lenses and, in some aspects, cylindrical lenses. These refractive elements may be mechanically coupled to the housing and therefore move with the latter.

FIG. 2 shows a plan view of a housing 12 with the light discharge bodies arranged therein. It can be seen that the individual light discharge bodies 8a, 8b, 8c are arranged diagonally or laterally offset relative to one another. In this way, the laser light sources 4a, 4b, 4c can be activated at different points in time. However, it would in principle also be possible to operate the individual laser light sources 4a, 4b, 4c continuously and to bring about an interruption by means of closing elements such as shutters or the like. It would also be possible to provide the entire housing at an angle in order in this way to achieve a lateral offset of the light discharge bodies. It would also be possible to vary a corresponding angled position.

In use, a method for inscribing container may include supplying laser light from a plurality of solid-state laser light sources to a plurality of light discharge bodies. The light discharge bodies may be arranged next to one another, wherein each light discharge body is coupled with a respective solid-state laser light source. Containers may be transported individually along a predefined path via a transport device such that the containers move relative to the light discharge bodies. Containers may be inscribed individually by directing light via the light discharge bodies as the containers are moved relative to the light discharge bodies.

It will be apparent to those skilled in the art that various modifications and variations can be made to the apparatuses and methods for inscribing containers of the present disclosure without departing from the scope of the invention. Other embodiments of the invention will be apparent to those skilled in the art from consideration of the specification and practice of the invention disclosed herein. It is intended that the specification and examples be considered as exemplary only.

What is claimed is:

1. Apparatus for inscribing containers, the apparatus comprising:
an inscription unit, the inscription unit comprising
a plurality of laser light sources, the laser light sources being solid-state lasers, and
a plurality of light discharge bodies arranged next to one another, each light discharge body being coupled with a respective one of the laser light sources, the light discharge bodies being configured to direct laser light from said laser light sources onto containers to be inscribed.

2. Apparatus according to claim 1, wherein the laser light sources are diode lasers.

3. Apparatus according to claim 1, wherein the light discharge bodies are connected to the laser light sources via a plurality of optical fibres.

4. Apparatus according to claim 1, wherein the light discharge bodies are arranged in a common housing.

5. Apparatus according to claim 1, wherein at least two of said light discharge bodies are offset relative to one another in a transport direction of the containers.

6. Apparatus according to claim 1, wherein the light discharge bodies are arranged along a diagonal line relative to a longitudinal direction of the container.

7. Apparatus according to claim 1, further comprising a transport device which transports the containers individually.

8. Apparatus according to claim 1, wherein the laser light sources emit radiation in a wavelength range between 700 nm and 1300 nm.

9. Apparatus according to claim 3, wherein the optical fibres run at least partially alongside one another.

10. Apparatus according to claim 1, wherein the individual laser light sources can be controlled independently of one another.

11. Apparatus according to claim 1, further comprising at least one refractive element arranged between the light discharge bodies and the container to be inscribed.

12. Apparatus according to claim 1, wherein the light discharge bodies can be moved jointly in a transport direction of the containers.

13. Apparatus according to claim 1, further comprising a control device, the control device controlling a movement of the light discharge bodies in a transport direction of the containers as a function of the transport speed of the containers.

14. Method for inscribing containers, comprising:
transporting containers individually via a transport device along a predefined path;
inscribing said containers individually during said transport by means of an apparatus for inscribing the containers, the apparatus for inscribing the containers comprising a plurality of light discharge bodies arranged next to one another and configured to direct laser light onto the containers, wherein the containers move relative to the light discharge bodies during the inscription, the light discharge bodies being supplied with laser light by a plurality of laser light sources, wherein the laser light sources are solid-state laser light sources.

15. Method according to claim 14, further comprising transmitting the laser light from the laser light sources to the light discharge bodies by means of a plurality of optical fibres.

16. Method for inscribing container, comprising:
supplying laser light from a plurality of solid-state laser light sources to a plurality of light discharge bodies, the light discharge bodies being arranged next to one another, each light discharge body being coupled with a respective solid-state laser light source;
transporting containers individually along a predefined path via a transport device such that the containers move relative to the light discharge bodies; and
inscribing the containers individually by directing light via the light discharge bodies as said containers are moved relative to the light discharge bodies.

17. Method according to claim 16, wherein said supplying step comprises directing laser light from the solid-state laser light sources to the light discharge bodies by means of a plurality of optical fibres.
